(19) United States
(12) Patent Application Publication
(10) Pub. No.: US 2025/0234531 A1
(43) Pub. Date: Jul. 17, 2025

(54) ONE-TIME PROGRAMMABLE BITCELL WITH A FUSE FIELD-EFFECT TRANSISTOR

(71) Applicant: Synopsys, Inc., Sunnyvale, CA (US)

(72) Inventor: Andrew Edward Horch, Seattle, WA (US)

(73) Assignee: Synopsys, Inc., Sunnyvale, CA (US)

(21) Appl. No.: 18/415,288

(22) Filed: Jan. 17, 2024

(51) Int. Cl. H10B 20/25; H01L 29/06; H01L 29/417; H01L 29/423; H01L 29/66; H01L 29/775; H01L 29/786

(52) U.S. Cl. CPC H10B 20/25; H10D 30/014; H10D 30/43; H10D 30/6729; H10D 30/6735; H10D 30/6755; H10D 30/6757; H10D 62/121

(57) ABSTRACT

A first current may be passed through a channel of a fuse field-effect transistor (FET) to heat a gate of the fuse FET. A second current may be passed between a first gate terminal and a second gate terminal of the gate of the fuse FET to permanently degrade one or more electrical characteristics of the fuse FET.

### TECHNICAL FIELD

The present disclosure relates to electronic circuits. More specifically, the present disclosure relates to a one-time programmable (OTP) bitcell with a fuse field-effect transistor (FET).

### BACKGROUND

An OTP bitcell may be a type of non-volatile memory (NVM) which stores a single bit of information, and which can be programmed so that the bitcell retains its state after the power supply is removed.

### BRIEF DESCRIPTION OF THE FIGURES

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIGS. 1A-1B illustrate an implementation of a fuse-based bitcell in accordance with some embodiments described herein.

FIGS. 1C-1F illustrate cross-sections of FETs manufactured using different technologies in accordance with some embodiments described herein.

FIG. 2A illustrates a top view of a fuse FET layout in accordance with some embodiments described herein.

FIG. 2B illustrates a cross-sectional view of a fuse FET device in accordance with some embodiments described herein.

FIGS. 3A-3B illustrate an implementation of a bitcell in accordance with some embodiments described herein.

FIGS. 4A-4B illustrate an implementation of a bitcell in accordance with some embodiments described herein.

FIGS. 5A-5B illustrate an implementation of a bitcell in accordance with some embodiments described herein.

FIGS. 6A-6B illustrate an implementation of a bitcell in accordance with some embodiments described herein.

FIGS. 7A-7B illustrate an implementation of a bitcell in accordance with some embodiments described herein.

FIG. 8 illustrates an implementation of a bitcell in accordance with some embodiments described herein.

FIG. 9 illustrates a process for programming a fuse FET in accordance with some embodiments described herein.

### DETAILED DESCRIPTION

Aspects of the present disclosure relate to an OTP bitcell with a fuse FET. A bitcell may include one or more FETs, and an FET may include a source, a drain, and a gate. The FET may include a channel (which may be constructed using an n-type material or a p-type material) between the source and drain. A dielectric material may separate the gate from the channel. A voltage difference between the gate and the drain may be used to modulate the amount of current that passes through the channel.

An anti-fuse FET may be used to implement an OTP bitcell. The anti-fuse FET may have (1) a first state which has a high resistance between the gate and the drain (or source), and (2) a second state which has a low resistance between the gate and the drain (or source). The anti-fuse may transition from the first state to the second state when a voltage greater than a rupture voltage threshold is applied across the gate and the channel (the channel voltage is between the source and drain voltages). Specifically, when a sufficiently high voltage is applied across the dielectric, the dielectric may break or rupture (i.e., the physical property of the dielectric material may change) and cause the gate to be electrically connected to the channel with a low resistance path through the dielectric material. In other words, when the dielectric material ruptures, the dielectric material becomes a conductor.

If a semiconductor manufacturing process allows multiple dielectric thicknesses, then a thinner dielectric may be used in an anti-fuse FET, and a thicker dielectric layer may be used in other FETs. A voltage greater than a rupture voltage threshold of the anti-fuse FET may be used to rupture the thinner dielectric in the anti-fuse FET, while protecting (i.e., not rupturing) the dielectric in the other FETs (i.e., the FETs that are not anti-fuse FETs) because the thicker dielectric of the other FETs can withstand the voltage which ruptures the thinner dielectric. Some circuit design techniques to split up the high voltage needed to rupture a gate over multiple devices are used to prevent excessive stress on any one of the peripheral devices. However, these techniques increase circuit complexity and size.

Some semiconductor manufacturing processes (which may include, but are not limited to, processes that are used to create nano-wire transistors and/or nano-sheet transistors) may only allow a single gate dielectric thickness. Additionally, the smaller spacing between devices in these processes may make the circuit less tolerant of elevated voltages. In such semiconductor manufacturing processes, it may be difficult to protect other FETs (i.e., the FETs that are not anti-fuse FETs) when rupturing the dielectric in the anti-fuse FETs.

Input/output (I/O) devices may refer to FETs which can operate at higher voltages and currents than non-I/O FETs sometimes called core devices. It is desirable to use I/O devices in circuits used to generate the high voltages which are used for rupturing the dielectric in an anti-fuse FET. However, some semiconductor manufacturing processes (which may include, but are not limited to, processes that are used to create nano-wire transistors and/or nano-sheet transistors) do not allow I/O devices and non-I/O devices to be manufactured in the same die. In such situations, excessive stress may be prevented by splitting the high voltage across multiple FETs. However, using multiple FETs increases the amount of circuit area used for generating the rupture voltages.

An additional problem is source/drain-to-well diode leakage. In some technologies, the source/drain-to-well diode breakdown can be lower than the desired rupture voltage for an anti-fuse OTP device. This may cause a problem in an array where a previously ruptured device may share a common gate line with devices which are desired to be ruptured. A previously ruptured device has a filament shorting the gate with the channel. The channel will pull the associated source/drain region to the rupture voltage. If the leakage of that N/P or P/N junction is too high, it may pull down the gate voltage and prevent other anti-fuse devices from being programmed (ruptured). It is desirable to reduce the voltage needed to program below the source/drain-to-well diode breakdown voltage.

An OTP bitcell may be implemented using a fuse instead of an anti-fuse, which may avoid the above-described problems with using anti-fuse FETs. A fuse may have two terminals and two states with different electrical characteristics. For example, in the first state, a low resistance may exist between the two terminals, and in the second state, a high resistance may exist between the two terminals. The fuse may be programmed by transitioning the fuse from the first state to the second state.

Some embodiments described herein use a fuse FET (instead of an anti-fuse FET) to implement an OTP bitcell. A fuse FET may include a first gate terminal and a second gate terminal. The fuse FET may have (1) a first state in which one or more electrical characteristics have a nominal value, and (2) a second state in which one or more electrical characteristics of the FET are permanently degraded with respect to the nominal value. The nominal values of the electrical characteristics may include, but are not limited to, a low resistance between the gate terminals, a high gain, a high drive current, and a low leakage current when the FET is off. The permanently degraded values of the electrical characteristics may include, but are not limited to, a high resistance between the gate terminals, a low gain, a low drive current, shifted threshold voltage (VT), and a high leakage current when the FET is off.

The fuse FET may transition from the first state to the second state when a first current is passed through the channel of the FET and a second current is passed through the fuse FET between the first gate terminal and the second gate terminal. When a current is passed between the first gate terminal and second gate terminal, electromigration may increase the temperature of the gate material, which may physically and/or chemically change the gate structure (e.g., because the increased temperature may deform or melt or move some of the material by electromigration at least a portion of the gate structure). The change in the gate structure may degrade one or more electrical characteristics of the fuse FET. Passing a current through the channel of the fuse FET may preheat the gate structure and make it easier to degrade one or more electrical characteristics of the fuse FET, i.e., it may lower the amount of gate current needed to transition the fuse FET to the second state.

In some FET manufacturing processes, different materials may be used to form the gate. The gate may be constructed using multiple layers to set the gate work function of the FET and provide low resistance connectivity. The gate work function has a strong influence on the VT of the FET. Materials used to set the gate work function may include, but are not limited to, TiN, TaN, and TiAl. These layers are adjacent to the gate dielectric. In gate all around (GAA) devices, these layers are wrapped around the nanosheet that contains the channel. A low resistance filler material may be added to the gate to fill in any spaces and provide a low resistance interconnect and place to connect to the gate. Tungsten (W) may be used as a low resistance fill material.

High current through the gate can permanently change the structure of the gate by electromigration or other means. The hotter the gate, the easier it is to change the gate's structure. Different materials are affected by heat and current. If the low resistance filler material shifts due to electromigration at lower temperatures and current densities than the other gate materials, then the resistance of the gate will change more than other device characteristics. If the materials used to set the work function are affected before the filler material than device characteristics such as VT, off state leakage, gain, will shift more than gate resistance.

Some embodiments described herein use self-heating properties of an FET to locally increase the temperature of the gate structure in a fuse FET. A thermal runaway may refer to a thermal positive feedback loop which is created when the heat generated by self-heating in the FET is greater than the heat lost (e.g., the heat lost through conduction). The term “self-heating” may refer to the heat which is generated by the FET itself as opposed to heat which is generated by another device that is in proximity to the FET. Thermal runaway may be triggered in an FET by using a combination of (1) preheating the FET by passing a current through the channel, (2) passing a current between the gate terminals, and (3) good thermal insulation in the structure of the FET. Some embodiments described herein cause thermal runaway to occur in a fuse FET, which causes the temperature of the gate structure in the fuse FET to increase, which causes permanent degradation of one or more electrical characteristics of the fuse FET. In some embodiments, additional heating elements may be added around the fuse. In some embodiments, the layout may be optimized to maximize thermal insulation of the fuse.

Technical advantages of embodiments described herein include, but are not limited to, (1) allowing implementation of an OTP bitcell in semiconductor manufacturing processes which allow a single gate dielectric thickness, (2) allowing implementation of an OTP bitcell in semiconductor manufacturing processes which do not include I/O devices, (3) allowing implementation of an OTP bitcell in semiconductor manufacturing processes which have smaller spacing between devices (and thus are less tolerant of elevated voltages which make it harder to use anti-fuse FETs), (4) reducing the area of circuits which generate voltages for programming OTP bitcells, (5) allowing lower programming voltages in processes where programming voltage without heating results in very high leakage (e.g., when the programming voltage is greater than the diode breakdown voltage).

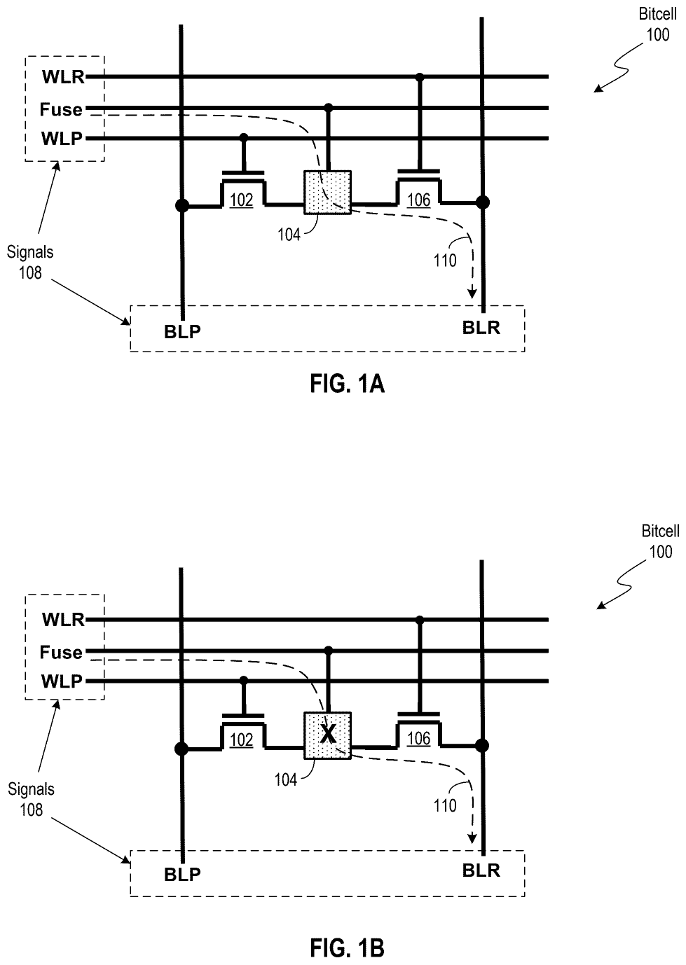

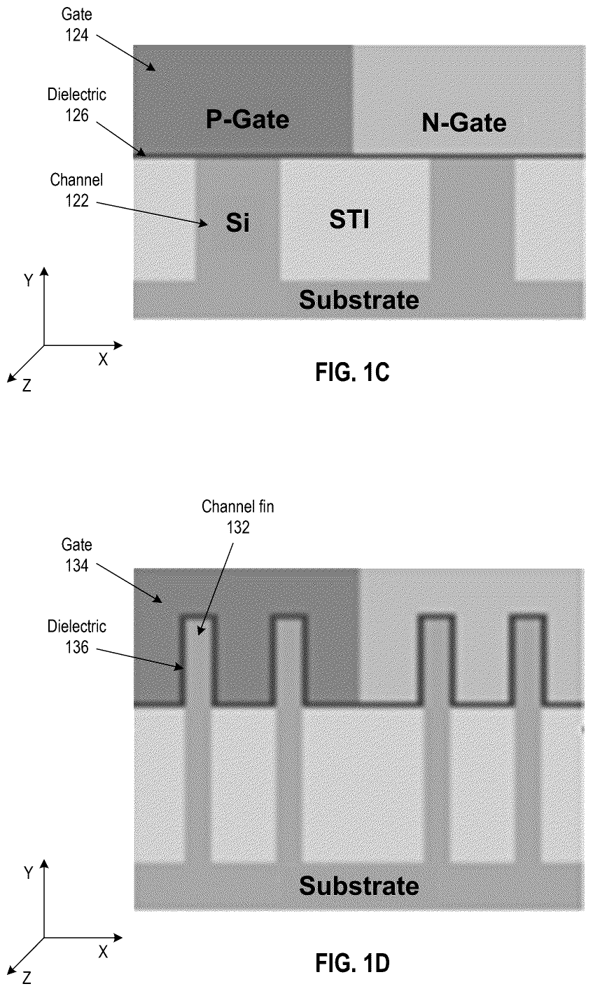

FIGS. 1A-1B illustrate an implementation of a fuse-based bitcell in accordance with some embodiments described herein.

Bitcell 100 may include FETs 102 and 106, and fuse device 104. FETs 102 and 106 may operate as pass transistors. Signals 108 may be used to program and read the contents of bitcell 100. Specifically, signals 108 may include a word-line read (WLR) signal, a fuse signal, a word-line program (WLP) signal, a bit-line read (BLR) signal, and a bit-line program (BLP) signal. In this disclosure, a filled circle (node) indicates an electrical connection between two intersecting wires. For example, the wire that carries the WLP signal is electrically connected to the gate of FET 102, the wire that carries the fuse signal is electrically connected to a terminal of fuse device 104, and the wire that carries the WLR signal is electrically connected to the gate of FET 106. Additionally, the wire that carries the BLP signal is electrically connected to the source of FET 102, and the wire that carries the BLR signal is electrically connected to the drain of FET 106. The term “wire” generally refers to a conducting path in a circuit which is used for carrying a signal. Examples of a wire include, but are not limited to, a structure made of doped polysilicon, and a metal trace in a metal layer of an integrated circuit.

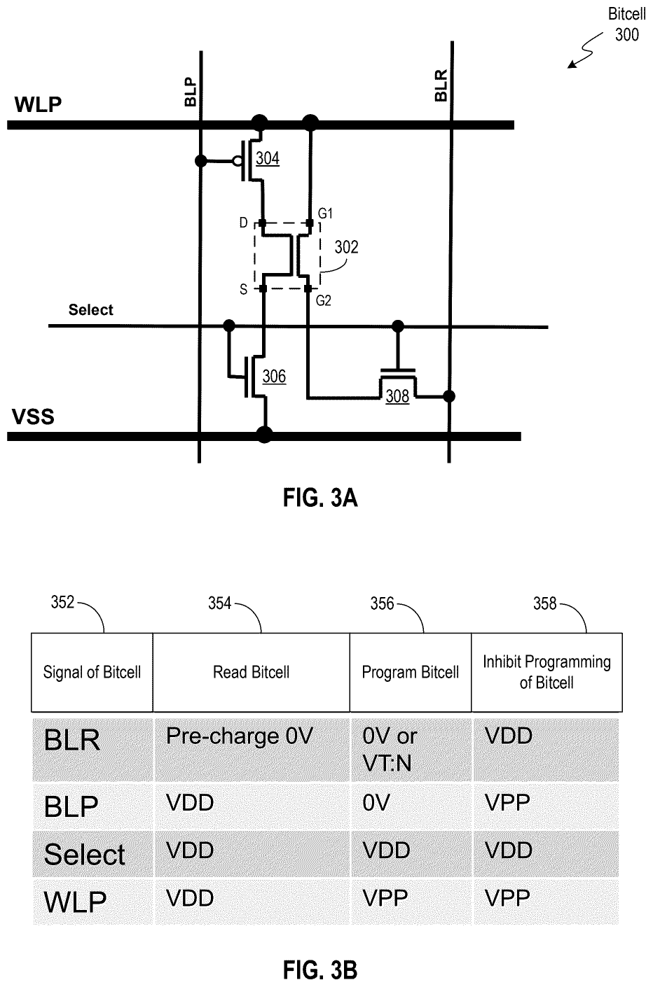

The WLR, BLR, and fuse signals may be used for reading the state (i.e., programmed or not programmed) of bitcell 100, and the state of bitcell 100 may correspond to a bit value (e.g., logic 0 or 1) which is stored in the bitcell. The WLR signal may be used to select a set of bitcells that belong to a word. The fuse signal may be maintained at a desired voltage (e.g., a voltage that corresponds to logic 0 or 1). If fuse device 104 has not been programmed (shown in FIG. 1A), then path 110 may have a low resistance, e.g., an electrical connection may exist between the fuse wire and the BLR wire. On the other hand, if fuse device 104 has been programmed (shown in FIG. 1B), then path 110 may have a high resistance, e.g., no electrical connection may exist between the fuse wire and the BLR wire. In other words, the voltage of the BLR signal will depend on whether the fuse device 104 has been programmed or not. The WLP, BLP, and fuse signals may be used for programming bitcell 100. For example, the WLP signal may be used to turn on FET 102, and the fuse and BLP signals may be used to program fuse device 104 by driving a high current through fuse device 104. Embodiments of bitcells which use a fuse FET are described below in reference to FIG. 3A through FIG. 8.

FIGS. 1C-1F illustrate cross-sections of FETs manufactured using different technologies in accordance with some embodiments described herein. In FIGS. 1C-1F, the X-direction is along the left-to-right direction, the Y-direction is along the bottom-to-top direction, and the Z-direction is perpendicular to the drawing page (i.e., the Z-direction comes out of the drawing page).

FIG. 1C illustrates a planar FET which includes gate 124, channel 122, and dielectric 126 which insulates gate 124 from channel 122. Channel 122 extends in the Z-direction, and the source and drain terminals of the FET are at the ends of channel 122.

FIG. 1D illustrates a fin FET which includes gate 134, channel fin 132, and dielectric 136 which insulates gate 134 from channel fin 132. Channel fin 132 extends in the Z-direction, and the source and drain terminals of the fin FET are at the ends of channel fin 132.

FIG. 1E illustrates a GAA FET which includes gate 144, channel 142, and dielectric 146 which insulates gate 144 from channel fin 142. Channel 142 extends in the Z-direction, and the source and drain terminals of the GAA FET are at the ends of channel 142. As shown in FIG. 1E, the gate 144 structure surrounds the channel 142 structure. Examples of GAA FET structures include, but are not limited to, nanowire-based FETs, nanoribbon-based FETs, and nanosheet-based FETs.

FIG. 1F illustrates a stacked GAA FET which includes gate 154, channel 152, and dielectric 156 which insulates gate 154 from channel 152. Channel 152 extends in the Z-direction, and the source and drain terminals of the stacked GAA FET are at the ends of channel 152. As shown in FIG. 1F, a p-channel GAA FET and an n-channel GAA FET may be stacked on top of each other.

Embodiments described herein may generally be used with FETs manufactured using any technology. Most of the heat may be dissipated through the source and drain, i.e., through the channel along the Z-direction in FIGS. 1C-1F. Some heat may also dissipate along the Y-direction in FIG. 1C. However, heat dissipation along the Y-direction is negligible in the fin FET structure shown in FIG. 1D and the GAA FET structures shown in FIGS. 1E-1F. Self-heating is a serious problem in the fin FET and GAA FET structures shown in FIGS. 1D-1F.

A place where the gate material narrows (with respect to other places in the gate) is a place where the resistance increases, and current is concentrated. In planer FETs, there are no places where the gate significantly narrows (pinches), which keep the gate resistance low, and the channel has a large area of contact with the substrate which aids heat dissipation. Therefore, there is less self-heating on planer FETs than FinFETs or GAA FETs. In FinFETs, the gate narrows as it goes over the fin (channel). This is due to the gate material being inlaid into a groove. The top of the fin is further away from the substrate than the bottom of the fin. This results in a place of high resistance above the fin to generate heat and a place in the channel that also generates heat and has reduced heat dissipation at the top of the fin. This makes FinFETs more susceptible to self-heating and thermal run away. GAA FETs are even more susceptible to self-heating and thermal run away. In GAA FETs, the pinch point in the gate is in between two channel regions.

Embodiments described herein use the thermal runaway in FETs for programming a fuse FET. For example, thermal runaway may be used to cause a permanent shift in a characteristic of the gate of the fuse FET and a permanent degradation of one or more electrical characteristics of the fuse FET. Specifically, some embodiments described herein may selectively cause thermal runaway to occur in a fuse FET which is desired to be programmed.

The electrical characteristics of a fuse FET may degrade negligibly over the lifespan of the fuse FET (e.g., 10 years) when the fuse FET is used within normal operating conditions. If the fuse FET is desired to be programmed (e.g., by using electromigration) in a short amount of time (e.g., 1 ms), then the degradation of the electrical characteristics may need to be accelerated substantially. Thermal runaway in the fuse FET can be used to achieve a high acceleration.

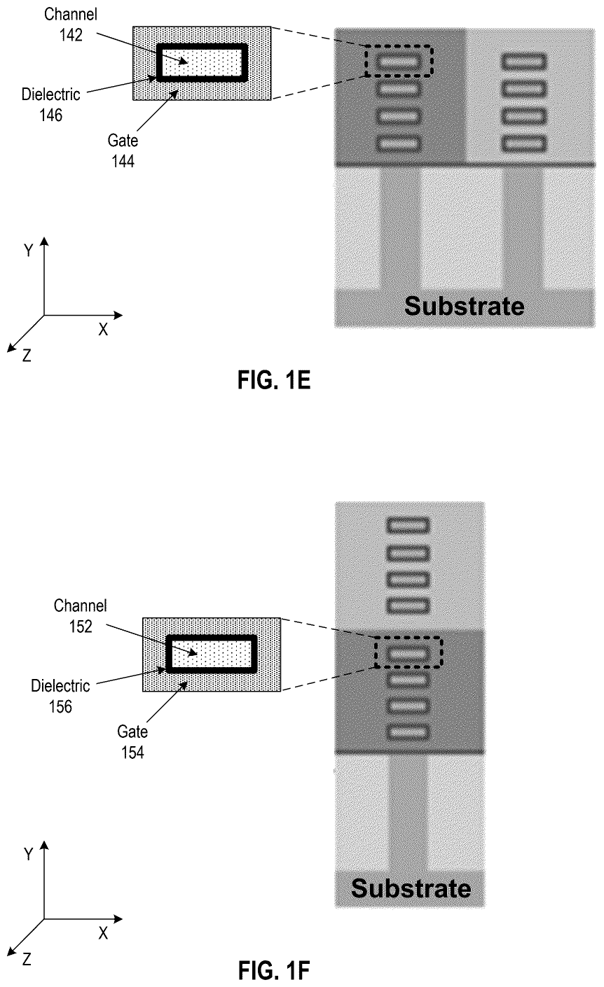

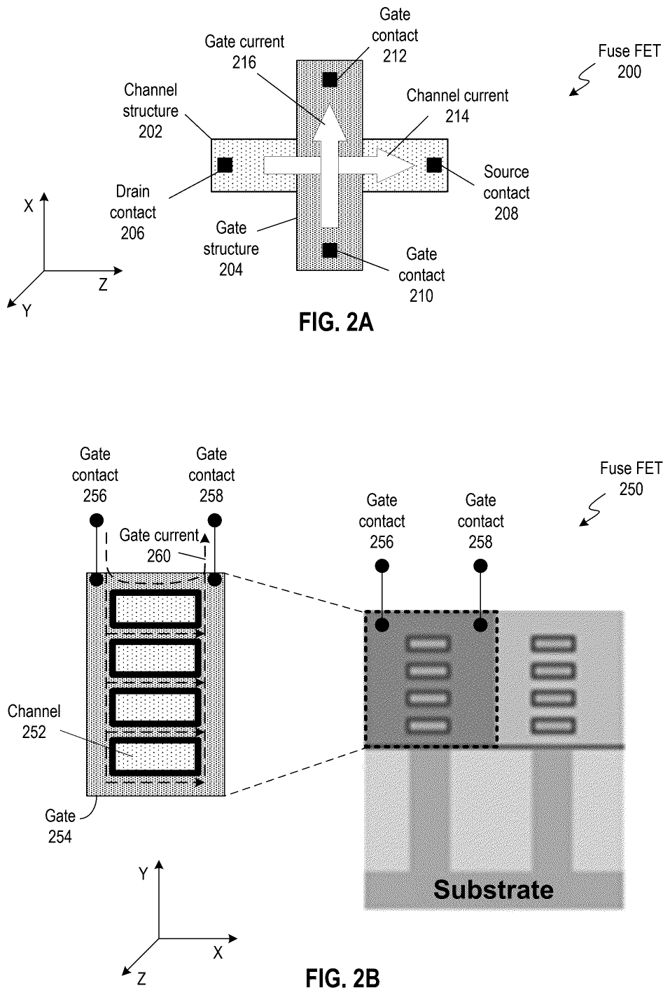

FIG. 2A illustrates a top view of a fuse FET layout in accordance with some embodiments described herein. In FIG. 2A, the X-direction is along the bottom-to-top direction, the Y-direction is perpendicular to the drawing page (i.e., the Y-direction comes out of the drawing page), and the Z-direction is along the left-to-right direction.

Fuse FET 200 may include an active region 202 and a gate structure 204. The term “active region” includes the source, drain, and channel, whereas the term “channel” refers to the active region which is under the gate. Thus, the active region in FIG. 2A includes the portion of active region 202 which is below gate structure 204. Gate contacts 210 and 212 may be electrically connected to gate structure 204. Drain contact 206 and source contact 208 may be electrically connected to active region 202. Channel current 214 may flow along the Z-direction from drain contact 206 to source contact 208. Gate current 216 may flow along the X-direction from gate contact 210 to gate contact 212.

FIG. 2B illustrates a cross-sectional view of a fuse FET device in accordance with some embodiments described herein. In FIG. 2B, the X-direction is along the left-to-right direction, the Y-direction is along the bottom-to-top direction, and the Z-direction is perpendicular to the drawing page (i.e., the Z-direction comes out of the drawing page).

Fuse FET 250 may include multiple channel structures, such as channel structure 252. Gate structure 254 may surround the multiple channel structures and a dielectric may separate gate structure 254 from the multiple channel structures. Gate contacts 256 and 258 may be electrically connected to gate structure 254. Channel current (not shown in FIG. 2B) may flow along the Z-direction from a drain contact (not shown in FIG. 2B) to a source contact (not shown in FIG. 2B). Gate current 260 may flow through the gate structure 254 along the X-direction from gate contact 256 to gate contact 258.

A direct current is typically not passed through a gate structure of an FET. In a typical FET, the gate structure may be made of a material which has low electromigration immunity, i.e., the temperature of the gate structure may increase quickly even when a small amount of direct current is passed through the gate structure. If a direct current is passed through a gate structure of a fuse FET, heat from the electromigration may deform or create a void in the gate structure, which may degrade the electrical characteristics of the fuse FET. The degradations in the electrical characteristics may include, but are not limited to, an increase in the gate resistance, an increase in the leakage current, a reduction in the gain, an increase in threshold voltage, and/or a reduction in the drive strength. In general, any of the degraded electrical characteristics of a fuse FET may be used to store a programmed value in the bitcell (i.e., the degraded electrical characteristic may be detected when reading the bitcell).

FIGS. 3A-3B illustrate an implementation of a bitcell in accordance with some embodiments described herein.

Bitcell 300 may include an NMOS fuse FET 302, PMOS FET 304, and NMOS FETs 306 and 308. The WLP wire may be electrically connected to the drain of the PMOS FET 304, the gate of the PMOS FET 304 may be electrically connected to the BLP wire, and the source of the PMOS FET 304 may be electrically connected to the drain of the NMOS fuse FET 302. The source of the NMOS fuse FET 302 may be electrically connected to the drain of NMOS FET 306, the source of NMOS FET 306 may be electrically connected to VSS (the term “VSS” may refer to the reference supply of 0V), and the gate of NMOS FET 306 may be electrically connected to the select wire.

A first gate terminal of the NMOS fuse FET 302 may be electrically connected to the WLP wire, and a second gate terminal of the NMOS fuse FET 302 may be electrically connected to the drain of the NMOS FET 308. The source of the NMOS FET 308 may be electrically connected to the BLR wire, and the gate of the NMOS FET 308 may be electrically connected to the select wire.

FIG. 3B illustrates the voltages which may be used for reading the contents of bitcell 300, programming bitcell 300, and inhibiting the programming of bitcell 300 (e.g., when a bitcell other than bitcell 300 is selected for programming). Column 352 specifies the signal wires, column 354 specifies the voltages which may be applied to the signal wires of a selected bitcell to read the contents of the selected bitcell, column 356 specifies the voltages which may be applied to the signal wires of a selected bitcell to program the selected bitcell, and column 358 specifies the voltages which may be applied to the signal wires of an unselected bitcell to inhibit programming of the unselected bitcell.

For example, to read a bitcell, column 354 specifies that, to read a selected bitcell, the BLR wire is pre-charged to 0V (the term “pre-charge” may refer to using a pre-charging circuit to set the line to a voltage and then let it float, to be pulled up or down by something else such as the bitcell), the BLP wire is set to VDD (the term “VDD” may refer to the positive power supply voltage, e.g., 5V), the select wire is set to VDD, and the WLP wire is set to VDD. For unselected bitcells during a read operation (i.e., the bitcells whose content is not desired to be read), the select wire may be set to 0V and the other wires may have the same voltage as shown in column 354.

To program a selected bitcell, column 356 specifies that, for the selected bitcell, the BLR wire is set to 0V or VT:N (the value “VT:N” may refer to the threshold voltage of an NMOS FET, i.e., the NMOS FET turns on when the gate-to-drain voltage is greater than or equal to VT:N), the BLP wire is set to 0V, the select wire is set to VDD, and the WLP wire is set to VPP (the term “VPP” may refer to a positive programming voltage which may be greater than VDD, e.g., 10V). To inhibit programming of an unselected bitcell, column 358 specifies that, for the unselected bitcell, the BLR wire is set to VDD, the BLP wire is set to VPP, the select wire is set to VDD, and the WLP wire is set to VPP.

During a read operation, the select wire is set at VDD and the BLR wire is pre-charged to 0V, which causes NMOS FET 308 to turn on, and which creates an electrical connection between the second gate terminal of NMOS fuse FET 302 and the BLR wire. If the resistance between two gate terminals of the NMOS fuse FET 302 is low (i.e., the NMOS fuse FET 302 has not been programmed), then a low resistance electrical connection will exist between the WLP wire and the BLR wire. On the other hand, if the resistance between two gate terminals of the NMOS fuse FET 302 is high (i.e., the NMOS fuse FET 302 has been programmed), then a high resistance electrical connection will exist between the WLP wire and the BLR wire. The bit stored in bitcell 300 may be read based on detecting the resistance between the WLP wire and the BLR wire.

To program bitcell 300, the voltages in column 356 may be used to pass a current through the channel of NMOS fuse FET 302 and a current between the two gate terminals of NMOS fuse FET 302. Specifically, the voltages in column 356 cause NMOS fuse FET 302, PMOS FET 304, NMOS FET 306, and NMOS FET 308 to be turned on, which causes a current to flow from the WLP wire to the VSS wire, and a current to flow from the WLP wire to the BLR wire. In some embodiments described herein, a current may be passed through the channel of NMOS fuse FET 302 to preheat NMOS fuse FET 302, and after NMOS fuse FET 302 has been preheated, a current may be passed through the two gate terminals of NMOS fuse FET 302. PMOS FET 304 may be turned off (e.g., by raising BLP to VDD) after thermal runaway begins in NMOS fuse FET 302. Fuse device 302 may be biased to ensure fuse device 302 is conducting a large amount of current. This may be achieved in a number of ways. For example, in FIG. 3B, the BLR voltage can be either 0V (VSS) or VT:N. The VT:N voltage is used to make the gate voltage a little higher to ensure the fuse device conducts enough current to program the fuse. The same result may be accomplished by making devices 304 and 306 much stronger than device 308. The fuse gate and channel voltages can be set voltage drops in the surrounding devices.

To inhibit programming of bitcell 300, the voltages in column 358 may be used. Specifically, the voltages in column 358 cause PMOS FET 304 and NMOS FET 308 to be off, which prevents a current from flowing through the channel of NMOS fuse FET 302 and prevents a current from flowing through the gate terminals of NMOS fuse FET 302.

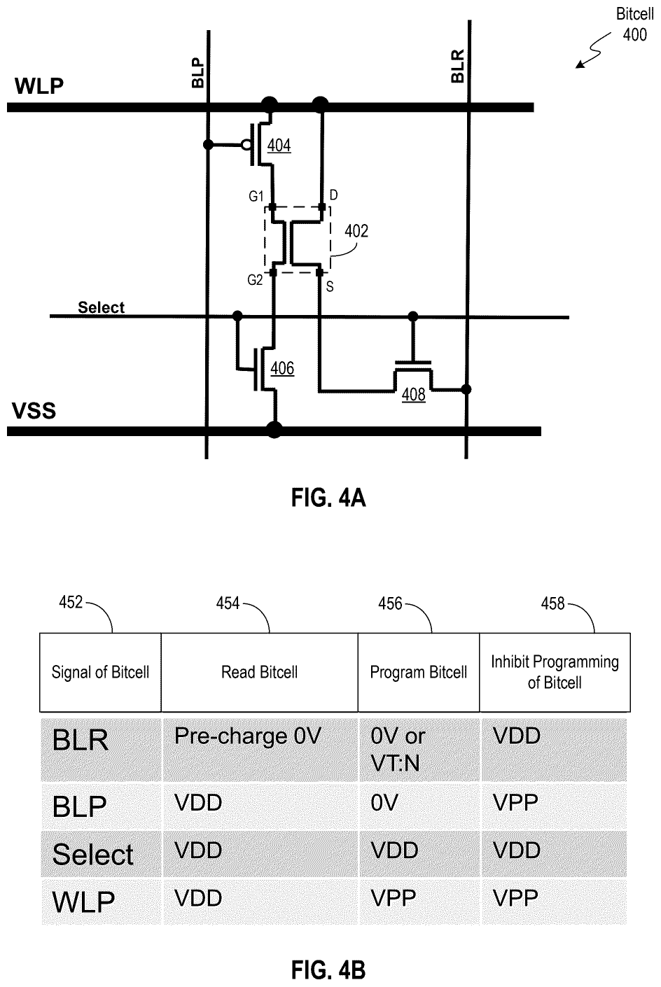

FIGS. 4A-4B illustrate an implementation of a bitcell in accordance with some embodiments described herein.

Bitcell 400 may include an NMOS fuse FET 402, PMOS FET 404, and NMOS FETs 406 and 408. The WLP wire may be electrically connected to the drain of the PMOS FET 404, the gate of the PMOS FET 404 may be electrically connected to the BLP wire, and the source of the PMOS FET 404 may be electrically connected to a first gate terminal of the NMOS fuse FET 402. The drain of the NMOS fuse FET 402 may be electrically connected to the WLP wire, the source of the NMOS fuse FET 402 may be electrically connected to the drain of NMOS FET 408, the source of NMOS FET 408 may be electrically connected to the BLR wire, and the gate of NMOS FET 406 may be electrically connected to the select wire. The second gate terminal of the NMOS fuse FET 402 may be electrically connected to the drain of the NMOS FET 406, and the source of the NMOS FET 406 may be electrically connected to VSS. The gate of the NMOS FET 406 may be electrically connected to the select wire.

FIG. 4B illustrates the voltages which may be used for reading the contents of bitcell 400, programming bitcell 400, and inhibiting the programming of bitcell 400 (e.g., when a bitcell other than bitcell 400 is selected for programming). Column 452 specifies the signal wires, column 454 specifies the voltages which may be applied to the signal wires of a selected bitcell to read the contents of the selected bitcell, column 456 specifies the voltages which may be applied to the signal wires of a selected bitcell to program the selected bitcell, and column 458 specifies the voltages which may be applied to the signal wires of an unselected bitcell to inhibit programming of the unselected bitcell.

For example, to read a bitcell, column 454 specifies that, for the selected bitcell, the BLR wire is pre-charged to 0V, the BLP wire is set to VDD, the select wire is set to VDD, and the WLP wire is set to VDD. For unselected bitcells during a read operation (i.e., the bitcells whose content is not desired to be read), the select wire may be set to 0V and the other wires may have the same voltage as shown in column 454. To program a selected bitcell, column 456 specifies that, for the selected bitcell, the BLR wire is set to 0V or VT:N, the BLP wire is set to 0V, the select wire is set to VDD, and the WLP wire is set to VPP. To inhibit programming of an unselected bitcell, column 458 specifies that, for the unselected bitcell, the BLR wire is set to VDD, the BLP wire is set to VPP, the select wire is set to VDD, and the WLP wire is set to VPP.

During a read operation, the select wire is set at VDD and the BLR wire is pre-charged to 0V, which causes NMOS FET 408 to turn on, and which creates an electrical connection between the source of NMOS fuse FET 402 and the BLR wire. If the channel resistance of the NMOS fuse FET 402 is low (i.e., the NMOS fuse FET 402 has not been programmed), then a low resistance electrical connection will exist between the WLP wire and the BLR wire. On the other hand, if the channel resistance of the NMOS fuse FET 402 is high (i.e., the NMOS fuse FET 402 has been programmed), then a high resistance electrical connection will exist between the WLP wire and the BLR wire. The bit stored in bitcell 400 may be read based on detecting the resistance between the WLP wire and the BLR wire. When the NMOS fuse FET 402 is programmed, current-voltage (IV) characteristics of NMOS fuse FET 402 may permanently degrade. Specifically, the degradation may prevent the gate from opening the channel, or cause poor gate control of the channel. The degraded NMOS fuse FET 402 may leak when the FET is off and/or the NMOS fuse FET 402 may have a low drive current. The degradation may be detected during a read operation.

To program bitcell 400, the voltages in column 456 may be used to pass a current through the channel of NMOS fuse FET 402 and a current between the two gate terminals of NMOS fuse FET 402. Specifically, the voltages in column 456 cause NMOS fuse FET 402, PMOS FET 404, NMOS FET 406, and NMOS FET 408 to be turned on, which causes a current to flow from the WLP wire to the VSS wire, and a current to flow from the WLP wire to the BLR wire.

To inhibit programming of bitcell 400, the voltages in column 458 may be used. Specifically, the voltages in column 458 cause PMOS FET 404 and NMOS FET 408 to be off, which prevents a current from flowing through the channel of NMOS fuse FET 402 and prevents a current from flowing through the gate terminals of NMOS fuse FET 402.

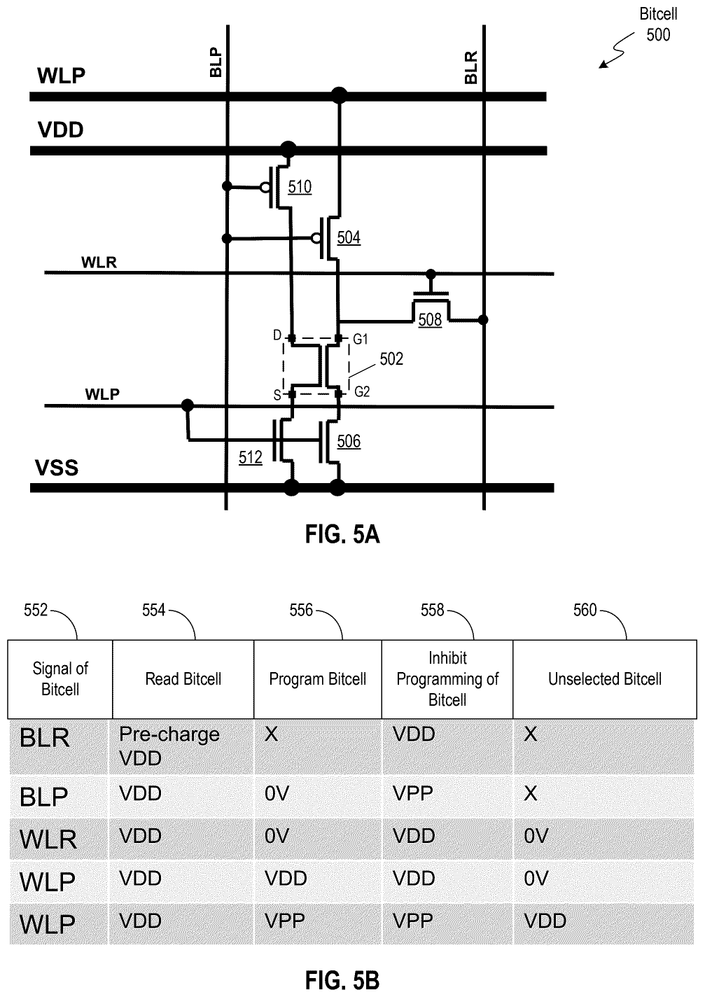

FIGS. 5A-5B illustrate an implementation of a bitcell in accordance with some embodiments described herein.

Bitcell 500 may include an NMOS fuse FET 502, PMOS FETs 504 and 510, and NMOS FETs 506, 508, and 512. The WLP wire may be electrically connected to the drain of the PMOS FET 504, the gate of the PMOS FET 504 may be electrically connected to the BLP wire, and the source of the PMOS FET 504 may be electrically connected to a first gate terminal of the NMOS fuse FET 502. The drain of the NMOS fuse FET 502 may be electrically connected to the source of NMOS FET 510, the drain of NMOS FET 510 may be electrically connected to VDD, and the gate of NMOS FET 510 may be electrically connected to the BLP wire. The source of the NMOS fuse FET 502 may be electrically connected to the drain of NMOS FET 512, the source of NMOS FET 512 may be electrically connected to VSS, and the gate of NMOS FET 512 may be electrically connected to the WLP wire. The second gate terminal of the NMOS fuse FET 502 may be electrically connected to the drain of the NMOS FET 506, and the source of the NMOS FET 506 may be electrically connected to VSS. The gate of the NMOS FET 506 may be electrically connected to the WLP wire. The first gate terminal of the NMOS fuse FET 502 may be electrically connected to the drain of NMOS FET 508, the source of NMOS FET 508 may be electrically connected to the BLR wire, and the gate of NMOS FET 508 may be electrically connected to the WLR wire.

FIG. 5B illustrates the voltages which may be used for reading the contents of bitcell 500, programming bitcell 500, and inhibiting the programming of bitcell 500 (e.g., when a bitcell other than bitcell 500 is selected for programming). Column 552 specifies the signal wires, column 554 specifies the voltages which may be applied to the signal wires of a selected bitcell to read the contents of the selected bitcell, column 556 specifies the voltages which may be applied to the signal wires of a selected bitcell to program the selected bitcell, column 558 specifies the voltages which may be applied to the signal wires to inhibit programming of a bitcell, and column 560 specifies the voltages which may be applied to the signal wires of an unselected bitcell. In FIG. 5B, the voltage “X” refers to a “don't care” voltage, e.g., the voltage may be equal to 0V or VDD or anything in between.

The bitcell shown is FIG. 5A may be used with a backside metal process. In some processes, active devices may be disposed between two metal stacks. A first metal stack (which may be referred to as the top-side metal) may be optimized for short distance high frequency signal transmission. Specifically, the first metal stack may have a lower capacitance to allow high speed signal transmission. A second metal stack (which may be referred to as the back-side metal) may be optimized for power transmission. The second metal stack may have lower resistance. In such processes, it may be desirable to route the high current programing signals on the back-side metal (i.e., the second metal stack) and the high frequency read operation signals on the top-side metal (i.e., the first metal stack). The layout of bitcell 500 shown in FIG. 5A is compatible with a process which uses two metal stacks. For example, the high current lines (e.g., WLP, VDD, and VSS) which may be used for programing may be routed in parallel on the back-side metal.

FIG. 5A also demonstrates one way to ensure the fuse transistor has both high gate current and channel current. During programming, the gate of the fuse is connected to a higher voltage than the drain ensuring the NMOS fuse FET 502 is on.

FIG. 5A also demonstrates one way to reduce the current needed to drive a node above VDD. If a voltage is above the proved power supplies in needed it might need to be generated by a charge pump. By having one of the current paths operate from an externally provided power supply, that reduces the current needed from the charge pump for the higher voltage.

There are many other ways to achieve the above bitcell operation. For example, if a PMOS device is used as a fuse, the gate needs to be below the well and source voltage.

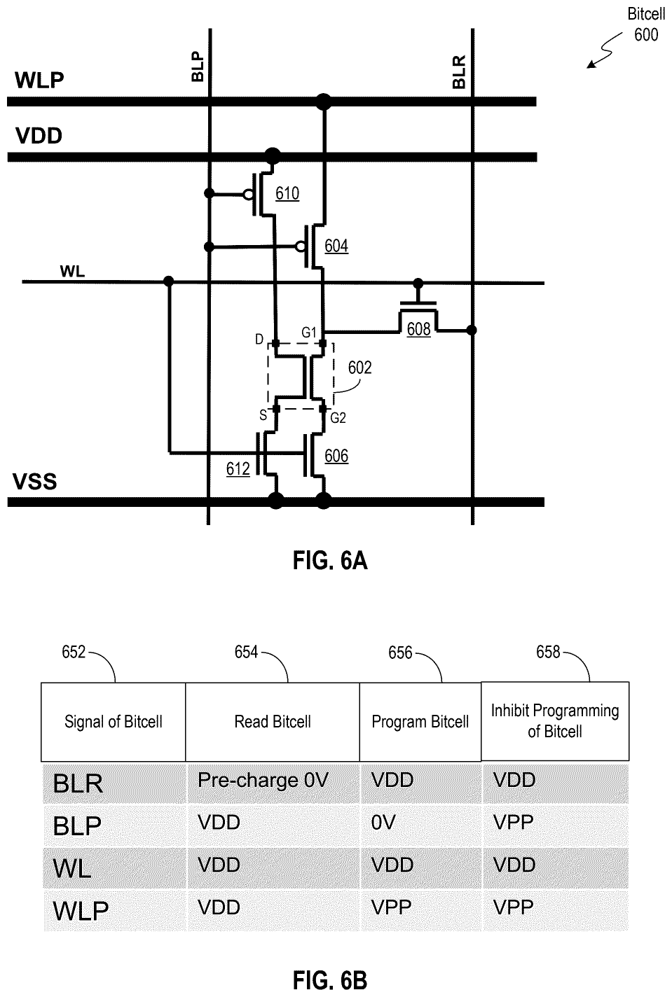

FIGS. 6A-6B illustrate an implementation of a bitcell in accordance with some embodiments described herein.

Bitcell 600 may include an NMOS fuse FET 602, PMOS FETs 604 and 610, and NMOS FETs 606, 608, and 612. The WLP wire may be electrically connected to the drain of the PMOS FET 604, the gate of the PMOS FET 604 may be electrically connected to the BLP wire, and the source of the PMOS FET 604 may be electrically connected to a first gate terminal of the NMOS fuse FET 602. The drain of the NMOS fuse FET 602 may be electrically connected to the source of NMOS FET 610, the drain of NMOS FET 610 may be electrically connected to VDD, and the gate of NMOS FET 610 may be electrically connected to the BLP wire. The source of the NMOS fuse FET 602 may be electrically connected to the drain of NMOS FET 612, the source of NMOS FET 612 may be electrically connected to VSS, and the gate of NMOS FET 612 may be electrically connected to the WL wire. The second gate terminal of the NMOS fuse FET 602 may be electrically connected to the drain of the NMOS FET 606, and the source of the NMOS FET 606 may be electrically connected to VSS. The gate of the NMOS FET 606 may be electrically connected to the WL wire. The first gate terminal of the NMOS fuse FET 602 may be electrically connected to the drain of NMOS FET 608, the source of NMOS FET 608 may be electrically connected to the BLR wire, and the gate of NMOS FET 608 may be electrically connected the WL wire.

FIG. 6B illustrates the voltages which may be used for reading the contents of bitcell 600, programming bitcell 600, and inhibiting the programming of bitcell 600 (e.g., when a bitcell other than bitcell 600 is selected for programming). Column 652 specifies the signal wires, column 654 specifies the voltages which may be applied to the signal wires of a selected bitcell to read the contents of the selected bitcell, column 656 specifies the voltages which may be applied to the signal wires of a selected bitcell to program the selected bitcell, and column 658 specifies the voltages which may be applied to the signal wires to inhibit programming of a bitcell.

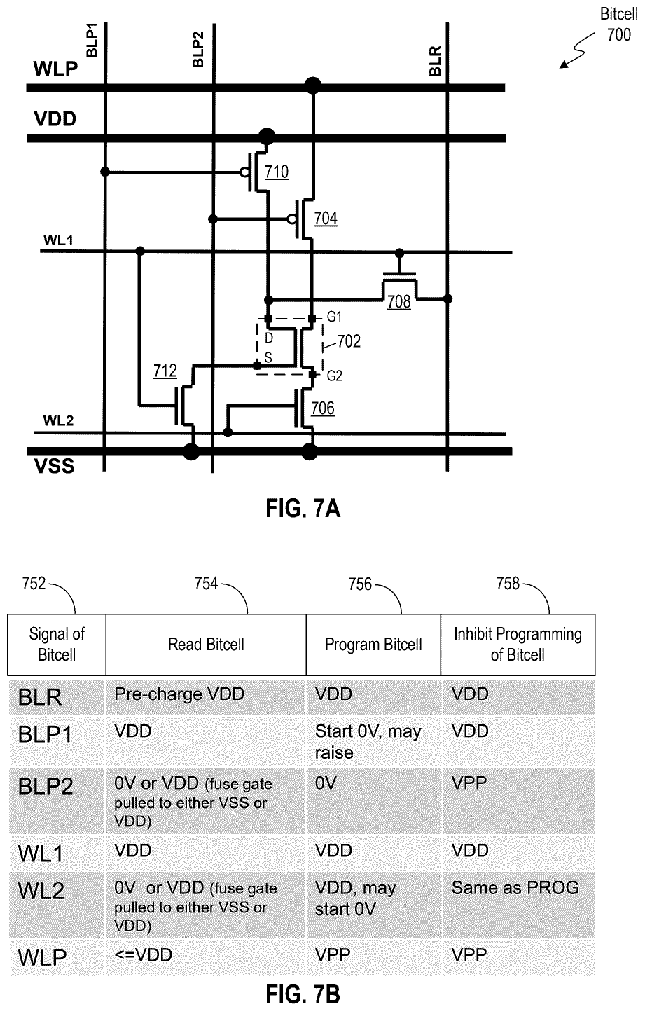

FIGS. 7A-7B illustrate an implementation of a bitcell in accordance with some embodiments described herein.

Bitcell 700 may include an NMOS fuse FET 702, PMOS FETs 704 and 710, and NMOS FETs 706, 708, and 712. The WLP wire may be electrically connected to the drain of the PMOS FET 704, the gate of the PMOS FET 704 may be electrically connected to the BLP2 wire, and the source of the PMOS FET 704 may be electrically connected to a first gate terminal of the NMOS fuse FET 702. The drain of the NMOS fuse FET 702 may be electrically connected to the source of NMOS FET 710, the drain of NMOS FET 710 may be electrically connected to VDD, and the gate of NMOS FET 710 may be electrically connected to the BLP1 wire. The source of the NMOS fuse FET 702 may be electrically connected to the drain of NMOS FET 712, the source of NMOS FET 712 may be electrically connected to VSS, and the gate of NMOS FET 712 may be electrically connected to the WL1 wire. The second gate terminal of the NMOS fuse FET 702 may be electrically connected to the drain of the NMOS FET 706, and the source of the NMOS FET 707 may be electrically connected to VSS. The gate of the NMOS FET 706 may be electrically connected to the WL2 wire. The drain the NMOS fuse FET 702 may be electrically connected to the drain of NMOS FET 708, the source of NMOS FET 708 may be electrically connected to the BLR wire, and the gate of NMOS FET 708 may be electrically connected the WL1 wire.

FIG. 7B illustrates the voltages which may be used for reading the contents of bitcell 700, programming bitcell 700, and inhibiting the programming of bitcell 700 (e.g., when a bitcell other than bitcell 700 is selected for programming). Column 752 specifies the signal wires, column 754 specifies the voltages which may be applied to the signal wires of a selected bitcell to read the contents of the selected bitcell, column 756 specifies the voltages which may be applied to the signal wires of a selected bitcell to program the selected bitcell, and column 758 specifies the voltages which may be applied to the signal wires to inhibit programming of a bitcell.

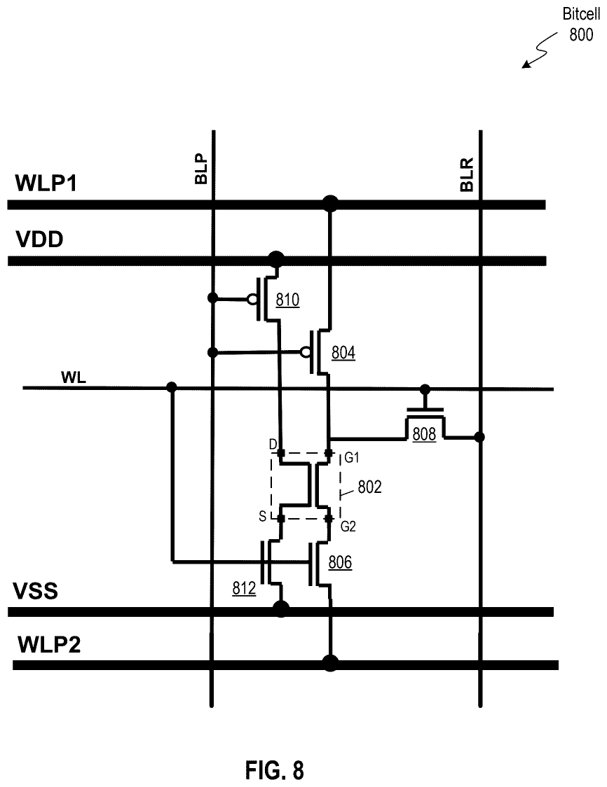

FIG. 8 illustrates an implementation of a bitcell in accordance with some embodiments described herein.

Bitcell 800 may include an NMOS fuse FET 802, PMOS FETs 804 and 810, and NMOS FETs 806, 808, and 812. The WLP1 wire may be electrically connected to the drain of the PMOS FET 804, the gate of the PMOS FET 804 may be electrically connected to the BLP wire, and the source of the PMOS FET 804 may be electrically connected to a first gate terminal of the NMOS fuse FET 802. The drain of the NMOS fuse FET 802 may be electrically connected to the source of NMOS FET 810, the drain of NMOS FET 810 may be electrically connected to VDD, and the gate of NMOS FET 810 may be electrically connected to the BLP wire. The source of the NMOS fuse FET 802 may be electrically connected to the drain of NMOS FET 812, the source of NMOS FET 812 may be electrically connected to VSS, and the gate of NMOS FET 812 may be electrically connected to the WL wire. The second gate terminal of the NMOS fuse FET 802 may be electrically connected to the drain of the NMOS FET 806, and the source of the NMOS FET 806 may be electrically connected to WLP2. The gate of the NMOS FET 806 may be electrically connected to the WL wire. The first gate terminal of the NMOS fuse FET 802 may be electrically connected to the drain of NMOS FET 808, the source of NMOS FET 808 may be electrically connected to the BLR wire, and the gate of NMOS FET 808 may be electrically connected the WL wire.

During programming, the voltage of the WLP1 wire can be set to a value that is substantially greater than VDD (e.g., two times VDD). During a read operation, the voltage of the WLP1 wire can be set to VDD. During programming, the voltage of the WLP2 wire can be set between 0V and VDD, e.g., VDD/2. During a read operation, the voltage of WLP2 wire can be set to VSS.

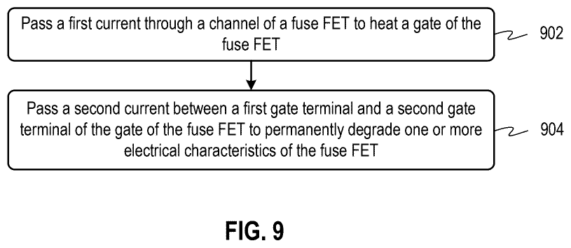

FIG. 9 illustrates a process for programming a fuse FET in accordance with some embodiments described herein.

A first current may be passed through a channel of a fuse FET to heat a gate of the fuse FET (at 902). For example, the first current may be the channel current 214 in FIG. 2A.

A second current may be passed between a first gate terminal and a second gate terminal of the gate of the fuse FET to permanently degrade one or more electrical characteristics of the fuse FET (at 904). For example, the second current may be the gate current 216 in FIG. 2A.

In some embodiments described herein, the first current may be passed concurrently with the second current. In some embodiments described herein, the second current may be passed after a time lag which allows the first current to heat the gate of the fuse FET. The time lag may be based on the design of the fuse FET and may be verified using simulation before the fuse FET is manufactured. In some embodiments described herein, the first current and the second current may cause thermal runaway in the gate of the fuse FET (e.g., the first current and the second current may be sufficiently large to cause thermal runaway).

In some embodiments described herein, the fuse FET may be an n-channel metal-oxide semiconductor FET. For example, fuse NMOS FET 302 in FIG. 3A may be an n-channel metal-oxide FET.

In some embodiments described herein, the fuse FET may be a p-channel metal-oxide semiconductor FET. For example, the polarity of the FETs shown in FIG. 3A may be reversed, i.e., NMOS fuse FET 302 may be replaced with a PMOS fuse FET, PMOS FET 304 may be replaced with an NMOS FET, and NMOS FETs 306 and 308 may be replaced with respective PMOS FETs. The polarity of the supply voltages shown in FIG. 3A may be reversed, and the polarity of voltages shown in FIG. 3B may be reversed.

In some embodiments described herein, the fuse FET may be a GAA FET. For example, fuse FET 250 is a GAA FET.

In some embodiments described herein, a read path to read a state of the fuse FET may pass through the first gate terminal and the second gate terminal. For example, the read path in FIG. 3A passes through the first gate terminal and the second gate terminal.

In some embodiments described herein, a read path to read a state of the fuse FET may pass through the channel of the fuse FET. For example, the read path in FIG. 4A passes through the first gate terminal and the second gate terminal.

In some embodiments described herein a bitcell (e.g., bitcell 300) may include a fuse FET (e.g., NMOS fuse FET 302) and a circuit (e.g., the circuit which includes PMOS FET 304 and NMOS FET 306), where the circuit may pass a first current through a channel of the fuse FET to heat a gate of the fuse FET and pass a second current between a first gate terminal and a second gate terminal of the gate of the fuse FET to permanently degrade one or more electrical characteristics of the fuse FET.

In some embodiments described herein, the circuit may include a first FET (e.g., PMOS FET 304 in FIG. 3A), a second FET (e.g., NMOS FET 306 in FIG. 3A), and a third FET (e.g., NMOS FET 308 in FIG. 3A). A source of the first FET may be electrically connected to a drain of the fuse FET (e.g., NMOS fuse FET 302 in FIG. 3A), a source of the fuse FET may be electrically connected to a drain of the second FET, and the second gate terminal of the gate of the fuse FET may be electrically connected to a drain of the third FET.

In some embodiments described herein, the circuit may include a first FET (e.g., PMOS FET 404 in FIG. 4A), a second FET (e.g., NMOS FET 406 in FIG. 4A), and a third FET (e.g., NMOS FET 408 in FIG. 4A). A source of the first FET may be electrically connected to the first gate terminal of the gate of the fuse FET (e.g., NMOS fuse FET 402 in FIG. 4A), a drain of the second FET may be electrically connected to the second gate terminal of the gate of the fuse FET, and a source of the fuse FET may be electrically connected to a drain of the third FET.

In some embodiments described herein, the circuit may include a first FET (e.g., PMOS FET 504 in FIG. 5A), a second FET (e.g., PMOS FET 510 in FIG. 5A), a third FET (e.g., NMOS FET 512 in FIG. 5A), and a fourth FET (e.g., NMOS FET 506 in FIG. 5A). A source of the first FET may be electrically connected to the first gate terminal of the gate of the fuse FET, a source of the second FET may be electrically connected to a drain of the fuse FET, a source of the fuse FET may be electrically connected to a drain of the third FET, and the second gate terminal of the gate of the fuse FET may be electrically connected to a drain of the fourth FET.

In some embodiments described herein, a first current may be passed through a channel of a fuse FET to heat a gate of the fuse FET. A second current may be passed between a first gate terminal and a second gate terminal of the gate of the fuse FET to permanently degrade one or more electrical characteristics of the fuse FET. Specifically, the first current and the second current may permanently change a characteristic or structure of the gate of the fuse FET.

In some embodiments described herein, the first current may be passed concurrently with the second current.

In some embodiments described herein, the second current may be passed after the first current heats the gate of the fuse FET.

In some embodiments described herein, the first current and the second current may cause thermal runaway in the gate of the fuse FET.

In some embodiments described herein, the fuse FET may be a p-channel metal-oxide semiconductor FET.

In some embodiments described herein, the fuse FET may be an n-channel metal-oxide semiconductor FET.

In some embodiments described herein, the fuse FET may be a gate-all-around (GAA) FET.

In some embodiments described herein, a read path to read a state of the fuse FET may pass through the first gate terminal and the second gate terminal.

In some embodiments described herein, a read path to read a state of the fuse FET may pass through the channel of the fuse FET.

In some embodiments described herein a bitcell may include a fuse FET and a circuit, where the circuit may pass a first current through a channel of the fuse FET to heat a gate of the fuse FET and pass a second current between a first gate terminal and a second gate terminal of the gate of the fuse FET to permanently degrade one or more electrical characteristics of the fuse FET.

In some embodiments described herein, the circuit may include a first FET, a second FET, and a third FET. A source of the first FET may be electrically connected to a drain of the fuse FET, a source of the fuse FET may be electrically connected to a drain of the second FET, and the second gate terminal of the gate of the fuse FET may be electrically connected to a drain of the third FET.

In some embodiments described herein, the circuit may include a first FET, a second FET, and a third FET. A source of the first FET may be electrically connected to the first gate terminal of the gate of the fuse FET, a drain of the second FET may be electrically connected to the second gate terminal of the gate of the fuse FET, and a source of the fuse FET may be electrically connected to a drain of the third FET.

In some embodiments described herein, the circuit may include a first FET, a second FET, a third FET, and a fourth FET. A source of the first FET may be electrically connected to the first gate terminal of the gate of the fuse FET, a source of the second FET may be electrically connected to a drain of the fuse FET, a source of the fuse FET may be electrically connected to a drain of the third FET, and the second gate terminal of the gate of the fuse FET may be electrically connected to a drain of the fourth FET.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method, comprising:
passing a first current through a channel of a fuse field-effect transistor (FET) to heat a gate of the fuse FET; and
passing a second current between a first gate terminal and a second gate terminal of the gate of the fuse FET to permanently degrade one or more electrical characteristics of the fuse FET.

2. The method of claim 1, wherein the first current is passed concurrently with the second current.

3. The method of claim 1, wherein the second current is passed after a time lag to allow the first current to heat the gate of the fuse FET.

4. The method of claim 1, wherein the first current and the second current cause thermal runaway in the gate of the fuse FET.

5. The method of claim 1, wherein the fuse FET is a p-channel metal-oxide semiconductor FET.

6. The method of claim 1, wherein the fuse FET is an n-channel metal-oxide semiconductor FET.

7. The method of claim 1, wherein the fuse FET is a gate-all-around FET.

8. The method of claim 1, wherein a read path to read a state of the fuse FET passes through the first gate terminal and the second gate terminal.

9. The method of claim 1, wherein a read path to read a state of the fuse FET passes through the channel of the fuse FET.

10. A bitcell, comprising:
a fuse field-effect transistor (FET); and
a circuit to:
pass a first current through a channel of the fuse FET to heat a gate of the fuse FET; and
pass a second current between a first gate terminal and a second gate terminal of the gate of the fuse FET to permanently degrade one or more electrical characteristics of the fuse FET.

11. The bitcell of claim 10, wherein the circuit comprises a first FET, a second FET, and a third FET, wherein a source of the first FET is electrically connected to a drain of the fuse FET, wherein a source of the fuse FET is electrically connected to a drain of the second FET, and the second gate terminal of the gate of the fuse FET is electrically connected to a drain of the third FET.

12. The bitcell of claim 10, wherein the circuit comprises a first FET, a second FET, and a third FET, wherein a source of the first FET is electrically connected to the first gate terminal of the gate of the fuse FET, wherein a drain of the second FET is electrically connected to the second gate terminal of the gate of the fuse FET, and wherein a source of the fuse FET is electrically connected to a drain of the third FET.

13. The bitcell of claim 10, wherein the circuit comprises a first FET, a second FET, a third FET, and a fourth FET, wherein a source of the first FET is electrically connected to the first gate terminal of the gate of the fuse FET, wherein a source of the second FET is electrically connected to a drain of the fuse FET, wherein a source of the fuse FET is electrically connected to a drain of the third FET, and wherein the second gate terminal of the gate of the fuse FET is electrically connected to a drain of the fourth FET.

14. The bitcell of claim 10, wherein the first current is passed concurrently with the second current.

15. The bitcell of claim 10, wherein the second current is passed after the first current heats the gate of the fuse FET.

16. The bitcell of claim 10, wherein the first current and the second current cause thermal runaway in the gate of the fuse FET.

17. The bitcell of claim 10, wherein a read path to read a state of the fuse FET passes through the first gate terminal and the second gate terminal.

18. A non-transitory computer-readable medium comprising stored instructions, which when executed by a processor, cause the processor to generate a digital representation of a structure, the structure comprising:
a fuse field-effect transistor (FET); and
a circuit to:
pass a first current through a channel of the fuse FET to heat a gate of the fuse FET;
pass a second current between a first gate terminal and a second gate terminal of the gate of the fuse FET; and
wherein the first current and the second current permanently shift a characteristic of the gate of the fuse FET, which permanently degrades one or more electrical characteristics of the fuse FET.

19. The non-volatile memory of claim 18, wherein the first current and the second current cause a thermal runway in the fuse FET.

20. The non-volatile memory of claim 18, wherein the first current and the second current cause electromigration in the gate of the fuse FET.
